(19) United States
(12) Patent Application Publication
(10) Pub. No.: US 2026/0351928 A1
(43) Pub. Date: Nov. 5, 2026

(54) MOUNTING PLATE FOR A SWITCH CABINET, AND PRODUCTION OF SAID MOUNTING PLATE

(71) Applicant: Siemens Aktiengesellschaft, 80333 München (DE)

(72) Inventor: Jens JÄHNICKE, Chemnitz (DE)

(73) Assignee: Siemens Aktiengesellschaft, 80333 München (DE)

(21) Appl. No.: 19/484,790

(22) PCT Filed: Mar. 19, 2024
(86) PCT No.: PCT/EP2024/057288

§ 371 Date: Nov. 14, 2025

(30) Foreign Application Priority Data
May 17, 2023 (EP) 23174009.3

(51) Int. Cl. H02B 1/20; H05K 1/05; H05K 3/12; H05K 3/46

(52) U.S. Cl. CPC H02B 1/207; H05K 1/053; H05K 3/1241; H05K 3/4685; H05K 2203/107; H05K 2203/128

(57) ABSTRACT

A mounting plate for a switchgear cabinet includes a carrier plate embodied as a carrier sheet and including an electrically isolating ceramic isolation layer attached to the carrier sheet, an electrically isolating ceramic functional layer attached to the electrically isolating ceramic isolation layer, and electrical conductors printed onto the functional layer.

The invention relates to a mounting plate for a switchgear cabinet and a method for the production thereof.

Electrical structural elements of a technical apparatus or installation are arranged in a switchgear cabinet. Electrical structural elements of this kind are contactors, switches, control units or input/output units, for example. In conventional switchgear cabinets, electrical structural elements are generally electrically connected by cables. In the case of a large number of electrical structural elements, this results in a high cabling outlay. The cabling of the electrical structural elements is a manual, staff-intensive and thus also expensive process.

M. Greifzu: “Funktionale Leiterbahnen aus dem 3D-Drucker” [“Functional conductor paths from the 3D printer”], Fraunhofer-Institut für Werkstoff-und Strahltechnik IWS [Fraunhofer Institute for Material and Beam Technology IWS] Dresden, Aug. 11, 2021, URL: https://www.iws.fraunhofer.de/de/newsundmedien/aktuelles/2021-08-11_aktuelles_leiterbahnen.html, discloses a method for printing conductor paths for high-power electronics onto a mounting plate via an additive manufacturing process.

DE 10 2016 002 052 A1 discloses a switchgear cabinet, which has at least one control panel with at least one baseplate, on which electrical switching elements are arranged and are electrically interconnected. The at least one baseplate and/or at least one of the electrical switching elements is produced by means of a 3D printer in a 3D printing method.

WO 2018/215547 A1 discloses a current distributor with a housing and a mounting plate arranged within the housing for mounting electrical functional structural elements. Starting from a front side, the mounting plate has multiple contacting recesses that run in the direction of a rear side.

The invention is based on the object of reducing the outlay for electrically connecting electrical structural elements of a switchgear cabinet.

The object is achieved according to the invention by a mounting plate for a switchgear cabinet with the features of claim 1, a method for producing the mounting plate with the features of claim 9, and a switchgear cabinet with the features of claim 13.

Advantageous embodiments of the invention are the subject matter of the subclaims.

A mounting plate according to the invention for a switchgear cabinet comprises
a carrier plate,
an electrically isolating ceramic functional layer that is attached to the carrier plate, and
electrical conductors that are printed onto the functional layer.

A mounting plate according to the invention for a switchgear cabinet thus has conductors which are printed onto a functional layer, wherein the functional layer is manufactured from an electrically isolating ceramic material, which is attached to a carrier plate. In this context, the printing process is a material extrusion process. The conductors printed onto the functional layer replace cables that are usually used to connect electrical structural elements of the switchgear cabinet. As a result, the cabling outlay for cabling of the electrical structural elements is advantageously reduced. Additionally, compared to cabling, printing the conductors enables an improved quality control, an improved heat dissipation of the electrical structural elements and conductors by the functional layer, as well as a material saving for the production of the conductors.

In one embodiment of the mounting plate according to the invention, the functional layer is manufactured from chromium oxide. Chromium oxide is particularly suitable as a material of the functional layer, as it effectively absorbs laser radiation, by which the functional layer is melted according to the method according to the invention for producing the mounting plate prior to the imprinting with the conductors (see below).

In a further embodiment of the mounting plate according to the invention, in each crossing region in which two conductors cross, an electrically isolating ceramic separating layer is printed between the two conductors, which electrically isolates the conductors from one another. The separating layer is manufactured from a glass, for example. The separating layer is thus likewise applied (printed) by material extrusion, so that the crossing regions of the conductors are produced using the same manufacturing method as the conductors.

In a further embodiment of the mounting plate according to the Invention, the functional layer imprinted with the electrical conductors is sealed with a coating. As a result, the conductors and the functional layer are advantageously protected from environmental influences.

The carrier plate of the mounting plate is a carrier sheet with an electrically isolating ceramic isolation layer that is applied to the carrier sheet and to which the functional layer is attached. The isolation layer is preferably manufactured from a material that has a higher melting temperature than the functional layer. For example, the isolation layer is manufactured from aluminum oxide. In this embodiment of the mounting plate according to the invention, the mounting plate thus has an electrically isolating ceramic isolation layer, which is arranged between the carrier sheet and the functional layer. This advantageously makes it possible to reduce the thickness of the functional layer, as its isolating effect is partially taken over by the isolation layer. The manufacturing of the isolation layer from a material that has a higher melting temperature, in particular a considerably higher melting temperature, than the functional layer is advantageous as this makes it possible to prevent the isolation layer from being melted by laser radiation by which the functional layer is melted according to the method according to the invention for producing the mounting plate prior to the printing of the conductors.

In the method according to the invention for producing a mounting plate according to the invention, the electrical conductors are printed onto the functional layer, by the regions of the functional layer to be imprinted with the electrical conductors initially being melted by laser radiation, and by melted conductor material subsequently being printed onto the melted regions. The melting of the regions of the functional layer to be imprinted with the electrical conductors prior to the imprinting of these regions with the conductor material advantageously improves the coupling of the conductor material into the functional layer and thus the adherence of the conductors to the functional layer. The use of laser radiation to melt the regions of the functional layer to be imprinted with the electrical conductors advantageously enables a melting of the functional layer that is locally restricted to the region of the functional layer to be imprinted.

In one embodiment of the method according to the invention, the functional layer is attached to the carrier plate by thermal spraying. This advantageously enables an inexpensive attachment of the functional layer to the carrier plate.

In a further embodiment of the method according to the invention, in each crossing region in which two conductors cross, initially a first conductor is printed onto the functional layer, subsequently the separating layer is printed onto the first conductor and the functional layer, and finally the second conductor is printed onto the separating layer. This advantageously also enables the production, already mentioned above, of the crossing regions of the conductors with the same method as the production of the conductors themselves.

In a further embodiment of the method according to the invention for producing a mounting plate, which has a carrier sheet with an electrically isolating ceramic isolation layer attached to the carrier sheet, the isolation layer is attached to the carrier sheet by thermal spraying. This advantageously enables an inexpensive attachment of the isolation layer to the carrier sheet.

The thickness of the carrier sheet is oriented toward the mechanical requirements with regard to the stability of the mounting plate and amounts to approx. 2 mm, for example. The thicknesses of the isolation layer and the functional layer result from material constants of said layers and their required dielectric strengths and amount to approx. 100 μm, for example.

A switchgear cabinet according to the invention has a mounting plate according to the invention. The advantages of a switchgear cabinet according to the invention correspond to the aforementioned advantages of a mounting plate according to the invention.

The above-described properties, features and advantages of this invention and the manner in which these are achieved will become clearer and more intelligible in conjunction with the following description of exemplary embodiments, which are illustrated in further detail in conjunction with the drawings. It is shown in:

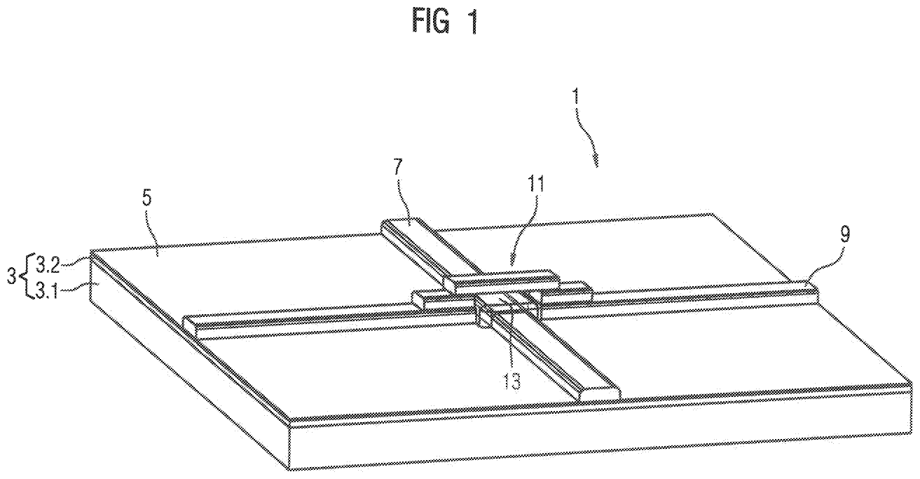

FIG. 1 a perspective representation of an exemplary embodiment of a mounting plate for a switchgear cabinet,

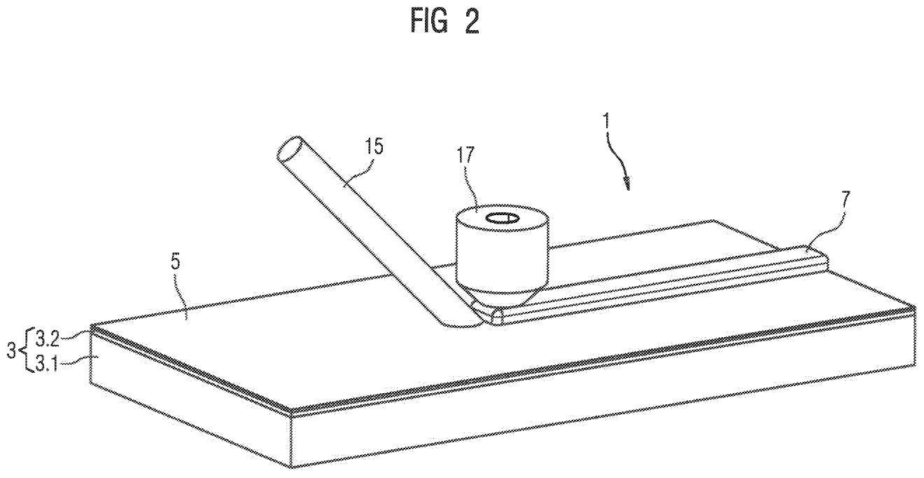

FIG. 2 a perspective representation of an exemplary embodiment of a mounting plate for a switchgear cabinet during the production thereof,

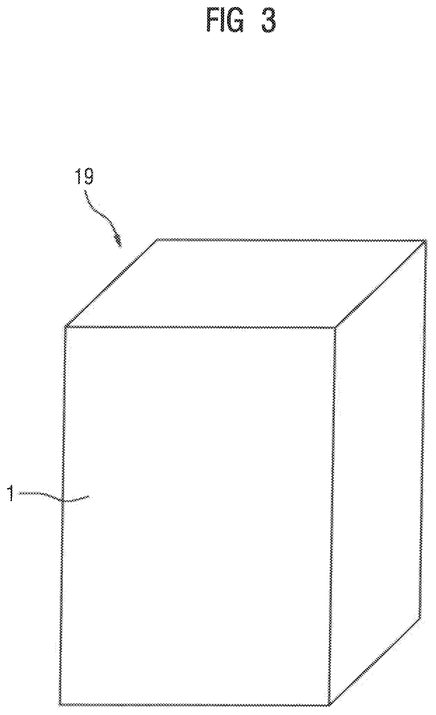

FIG. 3 a perspective representation of an exemplary embodiment of a switchgear cabinet.

Parts which correspond to one another are provided with the same reference characters in the figures.

FIG. 1 (FIG. 1) shows a perspective representation of an exemplary embodiment of a mounting plate 1 for a switchgear cabinet 19 (see FIG. 3).

The mounting plate 1 comprises a carrier plate 3, an electrically isolating ceramic functional layer 5 attached to the carrier plate 3, and electrical conductors 7, 9 printed onto the functional layer 5.

The functional layer 5 is manufactured from chromium oxide, for example.

The carrier plate 3 is a carrier sheet 3.1 with an electrically isolating ceramic isolation layer 3.2 that is attached to the carrier sheet 3.1 and to which the functional layer 5 is attached. The carrier sheet 3.1 is manufactured from a steel, for example. The isolation layer 3.2 is manufactured from a material that has a considerably higher melting temperature than the functional layer 5. For example, the isolation layer 3.2 is manufactured from aluminum oxide.

In the exemplary embodiment shown in FIG. 1, the mounting plate 1 has two conductors 7, 9 that cross in a crossing region 11. In the crossing region 11, an electrically isolating ceramic separating layer 13 is printed between the two conductors 7, 9, which electrically isolates the conductors 7, 9 from one another. The separating layer 13 is manufactured from a glass, for example.

FIG. 2 (FIG. 2) shows a perspective representation of an exemplary embodiment of a mounting plate 1 for a switchgear cabinet 19 during the production thereof.

The mounting plate 1 comprises a carrier plate 3, an electrically isolating ceramic functional layer 5 attached to the carrier plate 3, and an electrical conductor 7 printed onto the functional layer 5.

As in the exemplary embodiment shown in FIG. 1, the carrier plate 3 is a carrier sheet 3.1 with an electrically isolating ceramic isolation layer 3.2 that is attached to the carrier sheet 3.1 and to which the functional layer 5 is attached. The carrier sheet 3.1 is manufactured from a steel, for example. The isolation layer 3.2 is manufactured from a material that has a considerably higher melting temperature than the functional layer 5. For example, the isolation layer 3.2 is manufactured from aluminum oxide and is attached to the carrier sheet 3.1 by thermal spraying. For example, the functional layer 5 is manufactured from chromium oxide and is attached to the isolation layer 3.2 by thermal spraying.

The conductor 7 is printed onto the functional layer 5, by the regions of the functional layer 5 to be imprinted with the conductor 7 initially being melted by laser radiation 15, and by melted conductor material, which is output by a nozzle 17 onto the melted regions, subsequently being printed onto the melted regions.

To produce a crossing region 11 shown in FIG. 1, in which two conductors 7, 9 cross, initially a first conductor 7 is printed onto the functional layer 5 in the crossing region 11. Subsequently, the separating layer 13 is printed onto the first conductor 7 and the functional layer 5. Then, the second conductor 9 is printed onto the separating layer 5.

Subsequently, the functional layer 5 imprinted with the electrical conductors 7, 9 is sealed with a coating.

FIG. 3 (FIG. 3) shows a perspective representation of an exemplary embodiment of a switchgear cabinet 19. The switchgear cabinet 19 has a mounting wall 1 described on the basis of FIGS. 1 and 2, which forms a rear wall of the switchgear cabinet 19.

Although the invention has been illustrated and described in detail by way of exemplary embodiments, the invention is not restricted by the examples given and other variations can be derived therefrom by a person skilled in the art, without departing from the protective scope of the invention.

Independent of the grammatical term usage, individuals with male, female or other gender identities are included within the term.

What is claimed is: cm

1

.-

13

. (canceled)

14. A mounting plate for a switchgear cabinet, the mounting plate comprising:
a carrier plate embodied as a carrier sheet and comprising an electrically isolating ceramic isolation layer attached to the carrier sheet;
an electrically isolating ceramic functional layer attached to the isolation layer; and
electrical conductors printed onto the functional layer.

15. The mounting plate of claim 14, wherein the functional layer is made from chromium oxide.

16. The mounting plate of claim 14, further comprising an electrically isolating ceramic separating layer printed between two of the electrical conductors at a crossing region in which the two of the electrical conductors cross for electrically isolating the two of the electrical conductors from one another.

17. The mounting plate of claim 16, wherein the separating layer is made from a glass.

18. The mounting plate of claim 14, further comprising a coating designed to seal the functional layer imprinted with the electrical conductors.

19. The mounting plate of claim 14, wherein the isolation layer is made from a material that has a melting temperature which is higher than a melting temperature of the functional layer.

20. The mounting plate of claim 14, wherein the isolation layer is made from aluminum oxide.

21. The mounting plate of claim 14, wherein the carrier sheet is made from a steel.

22. A method for producing a mounting plate, the method comprising:
melting regions of an electrically isolating ceramic functional layer by laser radiation; and
printing melted conductor material subsequently onto the melted regions to form electrical conductors onto the functional layer.

23. The method of claim 22, further comprising manufacturing the functional layer from chromium oxide.

24. The method of claim 22, further comprising:
attaching an electrically isolating ceramic separating layer on a carrier sheet; and
printing the separating layer between two of the electrical conductors at a crossing region in which the two of the electrical conductors cross for electrically isolating the two of the electrical conductors from one another.

25. The method of claim 24, further comprising manufacturing the separating layer from a glass.

26. The method of claim 22, further comprising coating the functional layer Imprinted with the electrical conductors to seal the functional layer.

27. The method of claim 22, further comprising:
attaching the functional layer to an electrically isolating ceramic isolation layer; and
manufacturing the isolation layer from a material that has a melting temperature which is higher than a melting temperature of the functional layer.

28. The method of claim 27, wherein the isolation layer is made from aluminum oxide.

29. The method of claim 24, wherein the carrier sheet is made from a steel.

30. The method of claim 24, wherein the functional layer is attached to the separating layer by thermal spraying.

31. The method of claim 24, further comprising:
initially printing onto the functional layer a first one of the two of the conductors in the crossing region of the two of the conductors;
subsequently printing the separating layer onto the first one of the two of the conductors; and
subsequently printing onto the separating layer a second one of the two of the conductors.

32. The method of claim 27, further comprising attaching the isolation layer to a carrier sheet by thermal spraying.

33. A switchgear cabinet, comprising the mounting plate of claim 14.
